(19) United States
(12) Patent Application Publication
(10) Pub. No.: US 2025/0393229 A1
(43) Pub. Date: Dec. 25, 2025

(54) SEMICONDUCTOR DEVICE AND SEMICONDUCTOR MODULE

(71) Applicant: FUJI ELECTRIC CO., LTD., Kanagawa (JP)

(72) Inventors: Kazuki KAMIMURA, Matsumoto-city (JP); Tatsuya NAITO, Matsumoto-city (JP); Masahiro SASAKI, Azumino-city (JP)

(21) Appl. No.: 19/308,287

(22) Filed: Aug. 24, 2025

Related U.S. Application Data
(63) Continuation of application No. PCT/JP2024/027772, filed on Aug. 2, 2024.

(30) Foreign Application Priority Data
Sep. 4, 2023 (JP) 2023-143283

(51) Int. Cl. H10D 12/00; H01L 23/522; H10D 84/80; H10D 89/60

(52) U.S. Cl. CPC H10D 12/481; H01L 23/5228; H10D 84/817; H10D 89/921

(57) ABSTRACT

Provided is a semiconductor device including: a current detection portion through which a detection current corresponding to a main current of a transistor portion flows; a current detection pad which is arranged above a semiconductor substrate and arranged side by side with the current detection portion in a first direction; a built-in resistance portion which is provided above the semiconductor substrate and connects the current detection portion and the current detection pad; and a gate wiring which is arranged above the semiconductor substrate and is connected to the gate conductive portion, in which the built-in resistance portion and the gate wiring are arranged side by side in the first direction between the current detection portion and the current detection pad.

The contents of the following patent application(s) are incorporated herein by reference:
NO. 2023-143283 filed in JP on Sep. 4, 2023
NO. PCT/JP2024/027772 filed in WO on Aug. 2, 2024.

### BACKGROUND

### 1. Technical Field

The present invention relates to a semiconductor device and a semiconductor module.

### 2. Related Art

Conventionally, a semiconductor device having a current detection region is known (see, for example, Patent Documents 1 to 3).

### RELATED ART DOCUMENTS

### Patent Documents

Patent Document 1: Japanese Patent Application Publication No. H4-335560
Patent Document 2: Japanese Patent Application Publication No. H5-3289
Patent Document 3: Japanese Patent No. 3644697

### BRIEF DESCRIPTION OF THE DRAWINGS

FIG. 1 is a diagram illustrating an equivalent circuit of a semiconductor module 200 according to one embodiment of the present invention.

FIG. 2 is a diagram illustrating a relationship between a resistance value Rs (Ω) of a resistor connected to an emitter of a current detection portion 26 and a short circuit tolerance of the current detection portion 26.

FIG. 3 is a top view illustrating an example of a semiconductor device 100 according to one embodiment of the present invention.

FIG. 4 is an enlarged view of a region P in FIG. 3.

FIG. 5 is a view illustrating an example of a cross section A-A′ in FIG. 4.

FIG. 6 is a view illustrating an example of a cross section B-B′ in FIG. 4.

FIG. 7 is a view illustrating an example of a P region according to a first embodiment.

FIG. 8 is a view illustrating an example of a cross section A-A′ of FIG. 7.

FIG. 9 is a view illustrating an example of a P region according to a second embodiment.

FIG. 10 is an enlarged view of a built-in resistance portion 210.

FIG. 11 is a view illustrating an example of a cross section A-A′ of FIG. 9.

FIG. 12 is a view illustrating an example of a cross section C-C′ of FIG. 9.

FIG. 13 is a view illustrating an example of a P region according to a third embodiment.

FIG. 14 is a view illustrating an example of a cross section A-A′ of FIG. 13.

FIG. 15 is a view illustrating an example of a cross section C-C′ of FIG. 13.

FIG. 16 is a view illustrating an example of a P region according to a fourth embodiment.

FIG. 17 is a view illustrating an example of a cross section A-A′ of FIG. 16.

FIG. 18 is a view illustrating an example of a cross section C-C′ of FIG. 16.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to the solution of the invention. In the present specification, the same parts in each figure are denoted by the same signs and numerals, and descriptions thereof may be omitted. In addition, for convenience of description, some configurations may not be illustrated.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a specific direction. For example, a Z axis direction is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. As used herein, a direction of the Z axis may be referred to as the depth direction. In addition, as used herein, a direction parallel to the upper surface and the lower surface of the semiconductor substrate may be referred to as a horizontal direction, including an X axis direction and a Y axis direction.

In description of a circuit diagram, when arrangement of components such as placement of another component between two components is described, a positional relationship on an electric path is described. The description of the circuit diagram does not limit a positional relationship in space.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. As used herein, the impurities may particularly mean either a donor of the N type or an acceptor of the P type, and may be described as a dopant. As used herein, the doping means introducing the donor or the acceptor into the semiconductor substrate and turning it into a semiconductor presenting a conductivity type of the N type, or a semiconductor presenting a conductivity type of the P type. As used herein, the doping concentration of the region of the N type may be referred to as the donor concentration, and the doping concentration of the region of the P type may be referred to as the acceptor concentration.

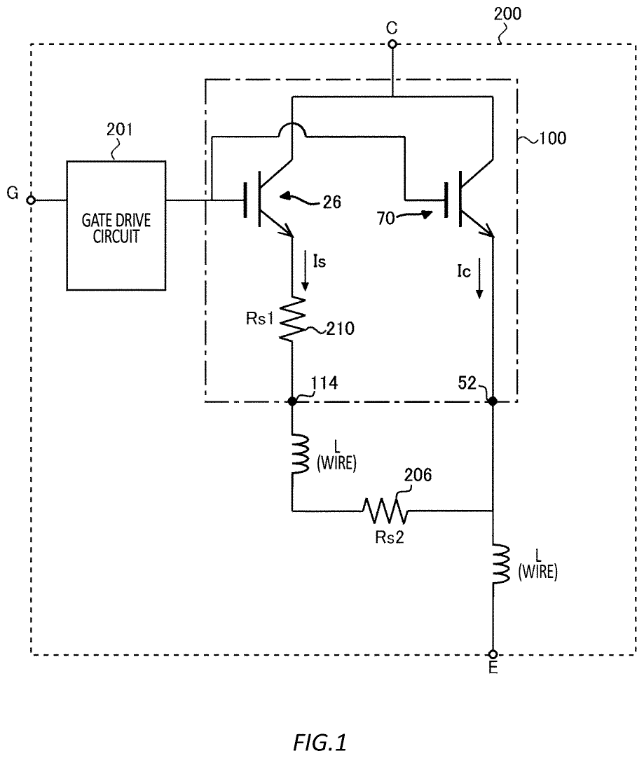

FIG. 1 is a diagram illustrating an equivalent circuit of a semiconductor module 200 according to one embodiment of the present invention. The semiconductor module 200 includes a semiconductor device 100, a gate drive circuit 201, and an external resistance portion 206. The semiconductor module 200 may include a housing which houses the semiconductor device 100, the gate drive circuit 201, and the external resistance portion 206. The housing may include an insulating material such as resin or ceramic. The semiconductor module 200 may include a plurality of semiconductor devices 100.

The semiconductor device 100 is a semiconductor chip including a power semiconductor such as an insulated gate bipolar transistor (IGBT). The semiconductor device 100 of the present example includes a transistor portion 70 and a current detection portion 26. The transistor portion 70 and the current detection portion 26 are provided on a same semiconductor substrate. The current detection portion 26 has a structure similar to that of the transistor portion 70. The current detection portion 26 and the transistor portion 70 in the present example each include a vertical IGBT. The transistor portion 70 and the current detection portion 26 are electrically provided in parallel, and the current detection portion 26 has an area smaller than that of the transistor portion 70 on the upper surface of the semiconductor substrate. Total channel widths of the transistor portion 70 and the current detection portion 26 are substantially proportional to their respective areas. Therefore, currents corresponding to their respective areas flow through the transistor portion 70 and the current detection portion 26. By sensing a detection current Is flowing through the current detection portion 26, a main current Ic flowing through the transistor portion 70 can be estimated.

A collector electrode of the transistor portion 70 and a collector electrode of the current detection portion 26 are connected to each other and are connected to a common collector terminal (C). The collector terminal (C) is a terminal provided in the semiconductor module 200, and is connected to an external circuit.

A gate electrode of the transistor portion 70 and a gate electrode of the current detection portion 26 are connected to the common gate drive circuit 201. The gate drive circuit 201 inputs a common gate signal to the transistor portion 70 and the current detection portion 26 to operate the transistor portion 70 and the current detection portion 26 in synchronization. The gate drive circuit 201 is connected to an external circuit via a gate terminal (G) provided in the semiconductor module 200.

The semiconductor device 100 includes an emitter electrode 52 and a current detection pad 114. The emitter electrode 52 is connected to an emitter of the transistor portion 70. The emitter electrode 52 is connected to an emitter terminal (E) of the semiconductor module 200 via wiring such as wires.

The current detection pad 114 is connected to an emitter of the current detection portion 26. The current detection pad 114 is separated from the emitter electrode 52 on the semiconductor substrate of the semiconductor device 100. The current detection pad 114 of the present example is connected to the external resistance portion 206 via wiring such as wires. The external resistance portion 206 is provided between the current detection pad 114 and the emitter terminal (E). The external resistance portion 206 is provided on a substrate different from the semiconductor substrate of the semiconductor device 100. For example, the semiconductor module 200 may have a circuit board on which the semiconductor device 100 and the external resistance portion 206 are placed. The semiconductor device 100 on the circuit board and the external resistance portion 206 on the circuit board are connected by wiring such as wires.

When the transistor portion 70 and the current detection portion 26 are turned on, the main current Ic and the detection current Is corresponding to their respective areas flow through the transistor portion 70 and the current detection portion 26. By measuring a voltage drop amount in the external resistance portion 206, the detection current Is flowing through the current detection portion 26 can be detected. The main current Ic of the transistor portion 70 can be estimated from the detection current Is. As a result, for example, it is possible to sense an overcurrent of the transistor portion 70 and stop the device.

The external resistance portion 206 is not incorporated in the semiconductor device 100, and various resistors can be connected to the semiconductor device 100. For example, a user of the semiconductor module 200 may prepare the external resistance portion 206 to incorporate the external resistance portion 206 into the semiconductor module 200.

When a resistance value Rs2 of the external resistance portion 206 is small, a large voltage may be applied across the collector and the emitter or across the gate and the emitter of the current detection portion 26. When a large voltage is applied to the current detection portion 26, the current detection portion 26 may be damaged.

The semiconductor device 100 of the present example includes a built-in resistance portion 210. The built-in resistance portion 210 is provided between the emitter of the current detection portion 26 and the current detection pad 114. The built-in resistance portion 210, the current detection pad 114, and the external resistance portion 206 are connected in series between the current detection portion 26 and the emitter terminal (E).

A resistance value Rs1 of the built-in resistance portion 210 is larger than the resistance value Rs2 of the external resistance portion 206. Accordingly, even when the resistance value Rs2 of the external resistance portion 206 is small, it becomes easy to maintain a resistance value of a combined resistor connected to the emitter of the current detection portion 26. Therefore, damage to the current detection portion 26 can be suppressed by reducing the voltage applied to the current detection portion 26.

The resistance value Rs1 of the built-in resistance portion 210 may be three times or more the resistance value Rs2 of the external resistance portion 206. Accordingly, it becomes easier to maintain the resistance value of the combined resistor connected to the emitter of the current detection portion 26. The resistance value Rs1 may be four times or more, or five times or more the resistance value Rs2.

The resistance value Rs1 of the built-in resistance portion 210 may be 10 times or less the resistance value Rs2 of the external resistance portion 206. Accordingly, the detection current Is is prevented from becoming excessively small. Accordingly, it is possible to maintain a detection accuracy of the detection current Is. The resistance value Rs1 may be eight times or less, or six times or less the resistance value Rs2.

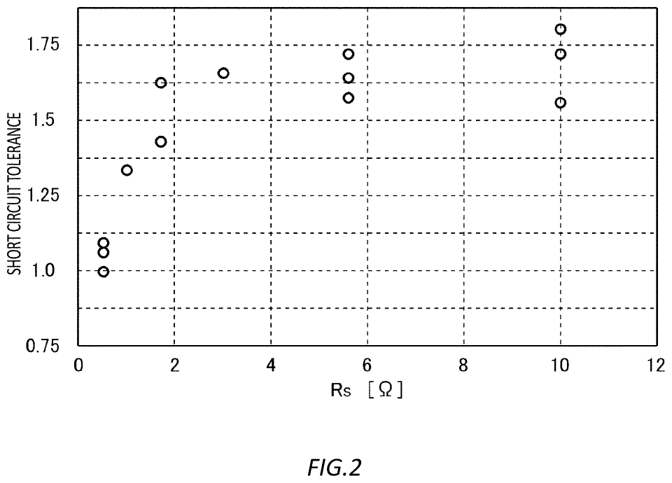

FIG. 2 is a diagram illustrating a relationship between a resistance value Rs (Ω) of a resistor connected to the emitter of the current detection portion 26 and a short circuit tolerance of the current detection portion 26. In FIG. 2, the short circuit tolerance is indicated by a ratio to a predetermined value (A/cm²). A circled plot in FIG. 2 indicates one measurement result. In the example of FIG. 1, the resistance value Rs is a sum of the resistance value Rs1 and the resistance value Rs2.

As illustrated in FIG. 2, as the resistance value Rs increases, the short circuit tolerance increases. In particular, up to a vicinity of the resistance value Rs of 6Ω, the short circuit tolerance greatly increases. Therefore, the resistance value Rs1 of the built-in resistance portion 210 may be 6Ω or more. Accordingly, it becomes easy to secure the short circuit tolerance of the current detection portion 26. The resistance value Rs1 may be 8Ω or more, or may be 10Ω or more. In a region where the resistance value Rs1 is 10Ω or more, the short circuit tolerance of the current detection portion 26 is relatively stable.

By providing the built-in resistance portion 210, the detection current Is flowing through the current detection portion 26 can be reduced. Accordingly, a gain (gm) in the current detection portion 26 can be reduced. Therefore, an oscillation of a waveform in the current detection portion 26 can be suppressed, and the short circuit tolerance can be increased.

The resistance value Rs1 of the built-in resistance portion 210 may be 20Ω or less. Accordingly, the detection current Is is prevented from becoming excessively small. The resistance value Rs1 may be 17Ω or less, or may be 15Ω or less.

The resistance value of the external resistance portion 206 may be 0.5Ω or more and less than 6Ω. The resistance value of the external resistance portion 206 may be 1Ω or more, or may be 1.5Ω or more. The resistance value of the external resistance portion 206 may be 5Ω or less, or may be 4Ω or less.

A rated current of the semiconductor device 100 is denoted by Ir (A). As the rated current Ir, a specification value of the semiconductor device 100 may be used. The resistance value Rs1 (Ω) of the built-in resistance portion 210 may be Ir/50 or more. The resistance value Rs1 may be Ir/40 or more, or may be Ir/30 or more. The resistance value Rs1 may be Ir/15 or less. The resistance value Rs1 may be Ir/20 or less, or may be Ir/25 or less.

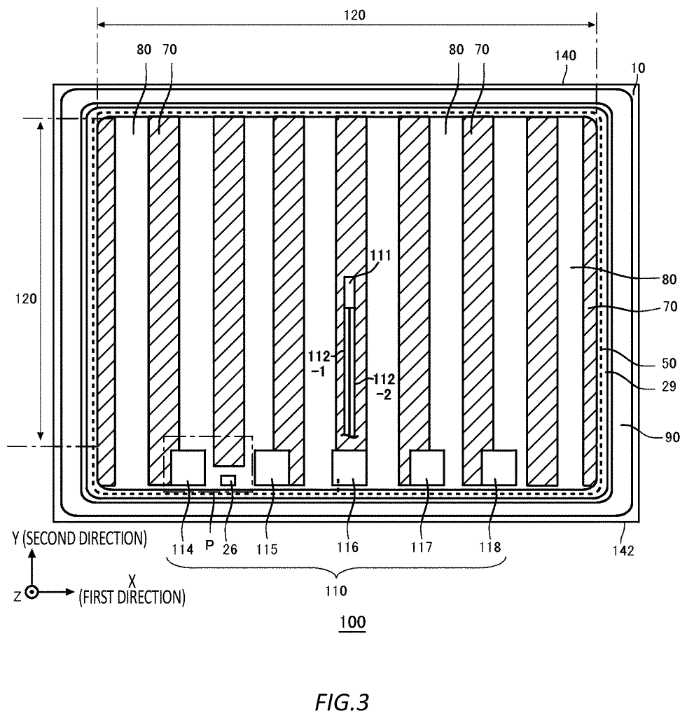

FIG. 3 is a top view illustrating an example of the semiconductor device 100 according to one embodiment of the present invention. FIG. 3 illustrates a position at which each member is projected on an upper surface of a semiconductor substrate 10. FIG. 3 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. In the present specification, end portions of an outer periphery of the semiconductor substrate 10 in top view are referred to as outer peripheral ends 140. The top view refers to a case of being viewed parallel to the Z axis from an upper surface side of the semiconductor substrate 10. In addition, any one end side of the outer peripheral ends 140 of the semiconductor substrate 10 in top view is defined as a first end side 142. A direction parallel to the first end side 142 in top view is defined as an X axis direction, and a direction perpendicular to the first end side 142 is defined as a Y axis direction.

The semiconductor substrate 10 is provided with an active portion 120. The active portion 120 is a region through which a main current flows in the depth direction between the upper surface and a lower surface of the semiconductor substrate 10 when the semiconductor device 100 operates. The emitter electrode 52 is provided above the active portion 120, but is omitted in FIG. 3.

The active portion 120 is provided with the transistor portion 70 including a transistor element such as an IGBT. The active portion 120 may further be provided with a diode portion 80 including a diode element such as a freewheeling diode (FWD). The transistor portion 70 and the diode portion 80 are provided inside the semiconductor substrate 10. In the example of FIG. 3, the transistor portion 70 and the diode portion 80 are alternately arranged along a first direction. Trench portions described later may also be arranged side by side along the first direction. In the present example, the transistor portion 70 is provided at an end of the active portion 120 in the first direction. In another example, the active portion 120 may be provided with only one of the transistor portion 70 and the diode portion 80.

Each of the transistor portion 70 and the diode portion 80 may be elongated in a second direction. A direction parallel to a longest straight line among boundary lines of constituent members in top view may be set as a longitudinal direction of the constituent members. The second direction is a direction in an XY plane and is a direction different from the first direction. In the present specification, the first direction is described as the X axis direction, and the second direction is described as the Y axis direction. A length of the transistor portion 70 in the Y axis direction is larger than its width in the X axis direction. Similarly, a length of the diode portion 80 in the Y axis direction is larger than its width in the X axis direction. A longitudinal direction of the transistor portion 70 and the diode portion 80, and a longitudinal direction of each trench portion described later may be the same.

The diode portion 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in top view. On the lower surface of the semiconductor substrate 10, a collector region of a P+ type may be provided in a region other than the cathode region. In the present specification, a region obtained by extending the diode portion 80 to an active well region 29 described later in the Y axis direction may also be included in the diode portion 80. The collector region is provided on a lower surface of the extended region.

The transistor portion 70 has the collector region of the P+ type in a region in contact with the lower surface of the semiconductor substrate 10. In addition, in the transistor portion 70, an emitter region of the N+ type, a base region of a P-type, and a gate structure including a gate conductive portion and a gate dielectric film are periodically arranged on the upper surface side of the semiconductor substrate 10.

A plurality of pad portions 110 (in the example of FIG. 3, the current detection pad 114, an auxiliary emitter pad 115, a gate pad 116, a cathode pad 117, and an anode pad 118) are provided above the upper surface of the semiconductor substrate 10. The current detection pad 114 is connected to the current detection portion 26.

The current detection portion 26 is provided inside the semiconductor substrate 10, and the detection current Is corresponding to the main current Ic of the transistor portion 70 flows. The current detection portion 26 has a same unit structure as that of the transistor portion 70, and has an area (corresponding to an area of a channel) smaller in top view than that of the transistor portion 70. The unit structure is repeatedly formed in the current detection portion 26 and the transistor portion 70. The unit structure includes, for example, a gate electrode, a gate dielectric film, an emitter region of the N+ type, and a base region of the P-type.

By detecting current flowing through the current detection portion 26, current flowing through a whole of the semiconductor device 100 can be estimated. As described in FIG. 1, the current detection pad 114 is connected to one end of the external resistance portion 206 by wiring such as wires. Another end of the external resistance portion 206 may be connected to the emitter electrode 52 via wiring such as wires. The another end of the external resistance portion 206 may also be connected to the emitter electrode 52 via the auxiliary emitter pad 115. The emitter electrode 52 is connected to the emitter terminal (E) via wiring such as wires.

The gate pad 116 is connected to the gate conductive portion of the transistor portion 70 and the gate conductive portion of the current detection portion 26. The gate conductive portion is an example of a gate electrode in a MOS gate structure. The gate pad 116 of the present example is connected to each gate conductive portion via a gate wiring 50. The gate wiring 50 is arranged between the active portion 120 and the end side 142 in top view. For example, the gate wiring 50 is arranged so as to surround the active portion 120 in top view. In FIG. 3, the gate wiring 50 is indicated by a broken line.

The gate wiring 50 may be a polysilicon wiring arranged above the upper surface of the semiconductor substrate 10. The gate wiring 50 and the semiconductor substrate 10 are insulated by a dielectric film. The gate wiring 50 may further include a metal wiring stacked with a polysilicon wiring with a dielectric film interposed therebetween. The polysilicon wiring and the metal wiring are connected via a contact hole provided in the dielectric film. By providing the gate wiring 50, a region away from the gate pad 116 can also transmit a gate voltage with low delay and low attenuation.

The cathode pad 117 and the anode pad 118 are connected to a temperature sensing portion 111 described later. Note that a number and type of the pad portions 110 provided on the semiconductor substrate 10 are not limited to the example illustrated in FIG. 3.

Each pad is formed of a metal material such as aluminum. The plurality of pad portions 110 are arrayed in a predetermined direction between the active portion 120 and the first end side 142 on the upper surface of the semiconductor substrate 10. The plurality of pad portions 110 of the present example are arranged to be sandwiched between the active portion 120 and the first end side 142 in the Y axis direction. The plurality of pad portions 110 of the present example are provided above the active well region 29 described later.

In an array direction of the plurality of pad portions 110, the current detection portion 26 may be provided between any two pad portions 110. The current detection portion 26 of the present example is arranged between two pad portions 110 in the first direction. The first direction of the present example and the array direction of the pad portions 110 are the same.

The semiconductor substrate 10 has the active well region 29. The active well region 29 encloses the transistor portion 70 and the diode portion 80 in top view. The active well region 29 encloses the active portion 120 in top view. The active well region 29 is a region of a second conductivity type which has a doping concentration higher than that of the base region. The active well region 29 in the present example is of the P+ type. The active well region 29 may enclose the active portion 120 along the gate wiring 50. The active well region 29 may be provided in the semiconductor substrate 10 below a region where the gate wiring 50 is provided. The active well region 29 is also provided around or below the pad portion 110, but is omitted in FIG. 3.

An edge termination structure portion 90 is provided between the active well region 29 and the outer peripheral end 140 of the semiconductor substrate 10 on the upper surface of the semiconductor substrate 10. The edge termination structure portion 90 may be annularly arranged so as to enclose the active well region 29 on the upper surface of the semiconductor substrate 10. The edge termination structure portion 90 of the present example is arranged along the outer peripheral end 140 of the semiconductor substrate 10. The edge termination structure portion 90 reduces an electric field strength on the upper surface side of the semiconductor substrate 10. For example, the edge termination structure portion 90 has a structure of a guard ring, a field plate, a RESURF, and a combination thereof.

A temperature sensing wiring 112 is provided above the active portion 120. The temperature sensing wiring 112 may be a semiconductor wiring. The temperature sensing wiring 112 is connected to the temperature sensing portion 111. The temperature sensing wiring 112 extends to a region between the active portion 120 and the outer peripheral end 140 on the upper surface of the semiconductor substrate 10, and is connected to the cathode pad 117 and the anode pad 118. Note that the semiconductor device 100 may not include the temperature sensing portion 111 and the temperature sensing wiring 112.

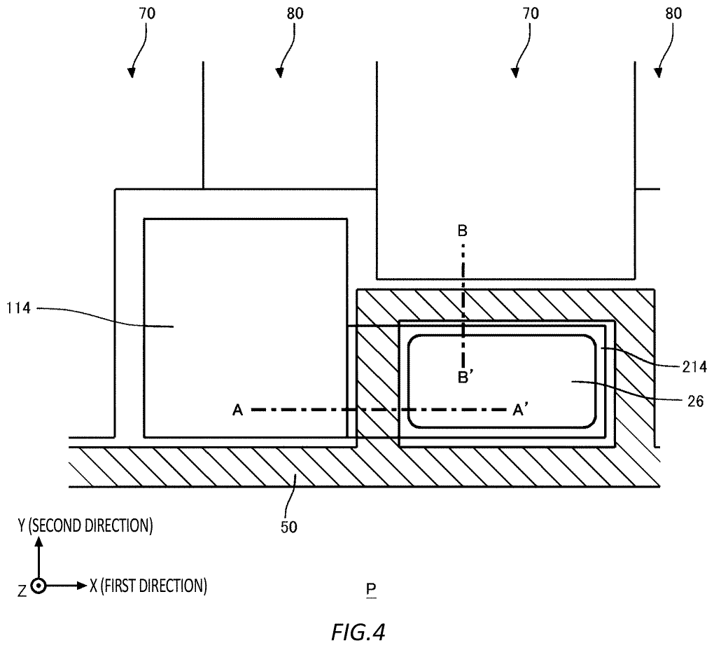

FIG. 4 is an enlarged view of a region P in FIG. 3. The region P includes the current detection pad 114 and the current detection portion 26. FIG. 4 illustrates the region P according to a reference example. The semiconductor device 100 of the reference example does not include the built-in resistance portion 210 described in FIG. 1.

The current detection pad 114 is arranged above the upper surface of the semiconductor substrate 10. In top view, the current detection pad 114 is arranged side by side with the current detection portion 26 in the first direction. Alignment of the current detection pad 114 and the current detection portion 26 in the first direction refers to a state where at least a part of the current detection pad 114 and at least a part of the current detection portion 26 face each other in the first direction. Wiring such as wires is connected to the upper surface of the current detection pad 114.

A current detection electrode 214 is provided above the current detection portion 26. The current detection electrode 214 is connected to an emitter region of the current detection portion 26. The current detection electrode 214 in the reference example is connected to the current detection pad 114. The current detection electrode 214 may be formed of a same material as that of the current detection pad 114. That is, the current detection electrode 214 in the reference example may be a portion where the current detection pad 114 extends. With such a structure, the detection current Is of the current detection portion 26 flows through the current detection electrode 214 and the current detection pad 114.

The gate wiring 50 of the present example is also arranged between the current detection pad 114 and the current detection portion 26 in top view. In the example of FIG. 4, the gate wiring 50 is provided so as to surround the current detection portion 26. The gate wiring 50 surrounding the current detection portion 26 may be connected to the gate conductive portion in the current detection portion 26. In addition, the gate wiring 50 surrounding the current detection portion 26 may also be connected to the gate conductive portion of the transistor portion 70.

In the example of FIG. 4, the current detection portion 26 is arranged to face the transistor portion 70 in the Y axis direction. In the present example, the gate wiring 50 is also provided between the current detection portion 26 and the transistor portion 70. The gate conductive portions of the current detection portion 26 and the transistor portion 70 may be connected to the gate wiring 50 between the current detection portion 26 and the transistor portion 70.

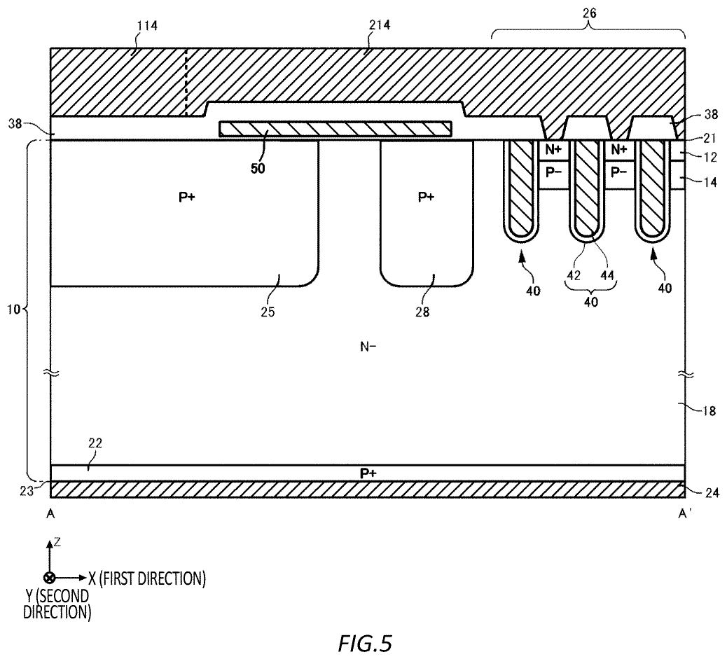

FIG. 5 is a view illustrating an example of a cross section A-A′ in FIG. 4. The cross section A-A′ is an XZ plane passing through the current detection portion 26 and the current detection pad 114. In the cross section A-A′, the semiconductor device 100 includes the semiconductor substrate 10, a collector electrode 24, an interlayer dielectric film 38, the current detection pad 114, the current detection electrode 214, and the gate wiring 50. The semiconductor substrate 10 has an upper surface 21 and a lower surface 23. The upper surface 21 and the lower surface 23 are two main surfaces of the semiconductor substrate 10.

The interlayer dielectric film 38 is provided on the upper surface 21 of the semiconductor substrate 10. The interlayer dielectric film 38 is a film including at least one layer of a dielectric film such as silicate glass to which impurities such as boron or phosphorous are added, a thermal oxide film, or other dielectric films.

The current detection pad 114 and the current detection electrode 214 are provided above the interlayer dielectric film 38. The current detection electrode 214 passes through a contact hole provided in the interlayer dielectric film 38 and is in contact with the upper surface 21 of the semiconductor substrate 10 on which the current detection portion 26 is provided. The current detection pad 114 is provided at a position not overlapping with the current detection portion 26, and is connected to the current detection electrode 214.

The gate wiring 50 is arranged above the upper surface 21 of the semiconductor substrate 10. A dielectric film such as the interlayer dielectric film 38 is provided between the gate wiring 50 and the semiconductor substrate 10. The gate wiring 50 is arranged below a metal electrode such as the current detection electrode 214. The gate wiring 50 and the metal electrode are insulated by the interlayer dielectric film 38.

The collector electrode 24 is provided on the lower surface 23 of the semiconductor substrate 10. The current detection pad 114, the current detection electrode 214, and the collector electrode 24 are formed of a metal material such as aluminum.

The current detection portion 26 includes a trench portion 40, an emitter region 12 of the N+ type, a base region 14 of the P− type, a drift region 18 of an N− type, and a collector region 22 of the P+ type. The trench portion 40 is provided from the upper surface 21 of the semiconductor substrate 10 toward the inside. In the present example, a plurality of trench portions 40 are arrayed along the first direction (X axis direction), and each trench portion 40 is elongated in the second direction (Y axis direction). The trench portion 40 includes a gate dielectric film 42 and a gate conductive portion 44. The gate dielectric film 42 is provided to cover an inner wall of a trench. The gate dielectric film 42 may be formed by oxidizing or nitriding a semiconductor on the inner wall of the trench. The gate conductive portion 44 is provided inside from the gate dielectric film 42 inside the trench. That is, the gate dielectric film 42 insulates the gate conductive portion 44 from the semiconductor substrate 10. The gate conductive portion 44 is formed of a conductive material such as polysilicon. In a cross section different from FIG. 5, the gate conductive portion 44 is electrically connected to the gate wiring 50. Some of the trench portions 40 may function as dummy trench portions in which an emitter potential is applied to the gate conductive portion 44.

In the X axis direction, the emitter region 12 and the base region 14 are provided between two trench portions 40. The emitter region 12 is exposed on the upper surface 21 of the semiconductor substrate 10 and is connected to the current detection electrode 214. The base region 14 is in contact with the trench portion 40 between the emitter region 12 and the drift region 18. When a predetermined gate voltage is applied to the gate conductive portion 44 of the trench portion 40, a surface layer of the base region 14 in contact with the trench portion 40 is inverted to an N-type region, and a channel is formed. Accordingly, the emitter region 12 and the drift region 18 are connected by the channel, and the detection current Is flows.

The collector region 22 is provided on the lower surface 23 of the semiconductor substrate 10. The collector region 22 is in contact with the collector electrode 24. An acceptor concentration of the collector region 22 is higher than an acceptor concentration of the base region 14. With such a structure, the current detection portion 26 operates as an IGBT.

Similarly to the current detection portion 26, the transistor portion 70 also includes the trench portion 40, the emitter region 12 of the N+ type, the base region 14 of the P− type, the drift region 18 of the N− type, and the collector region 22 of the P+ type. However, the transistor portion 70 is provided with more trench portions 40 than those of the current detection portion 26.

The diode portion 80 may also include a plurality of trench portions 40. However, the trench portion 40 of the diode portion 80 functions as the dummy trench portion described above. In addition, the diode portion 80 is not provided with the emitter region 12. In the diode portion 80, the base region 14 may be provided instead of the emitter region 12. In the diode portion 80, a cathode region of the N+ type is provided instead of the collector region 22.

A sense well region 28 may be provided in the semiconductor substrate 10. The sense well region 28 is a P+ type region exposed on the upper surface 21 of the semiconductor substrate 10. The sense well region 28 may be provided to a position deeper than that of the trench portion 40. The sense well region 28 may enclose the current detection portion 26 in top view. By providing the sense well region 28, the current detection portion 26 can be separated from the active portion 120 or the like, and the detection current Is can be accurately detected.

A pad well region 25 may be provided in the semiconductor substrate 10. The pad well region 25 is a P+ type region exposed on the upper surface 21 of the semiconductor substrate 10. The pad well region 25 may be provided to a position deeper than that of the trench portion 40. The pad well region 25 overlaps with at least a part of the current detection pad 114 in top view. The pad well region 25 may overlap with a whole of the current detection pad 114. The pad well region 25 may overlap with a part of the current detection electrode 214. The pad well region 25 may be connected to the sense well region 28.

At least a part of the gate wiring 50 may overlap with at least one of the pad well region 25 or the sense well region 28. In the present example, both end portions of the gate wiring 50 in the X axis direction overlap with the pad well region 25 or the sense well region 28.

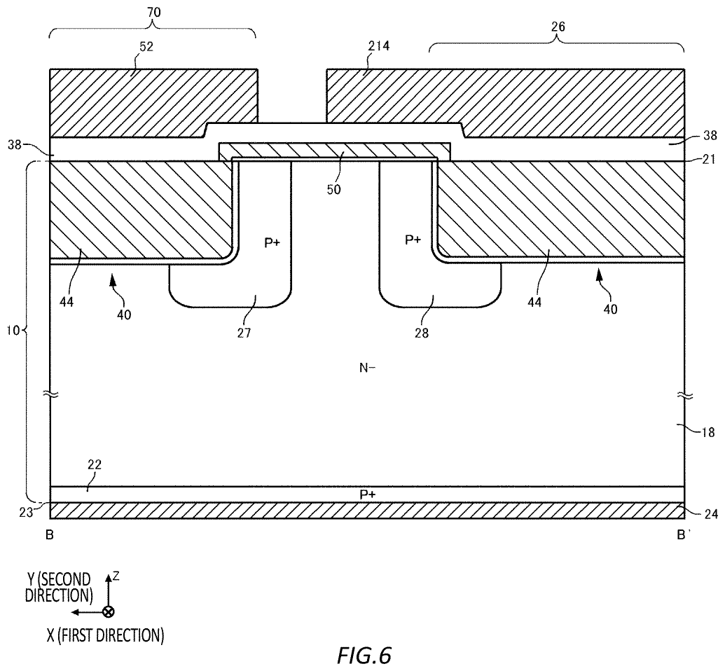

FIG. 6 is a view illustrating an example of a cross section B-B′ in FIG. 4. The cross section B-B′ is a YZ plane passing through the current detection portion 26 and the transistor portion 70. In the cross section B-B′, the semiconductor device 100 includes the semiconductor substrate 10, the collector electrode 24, the interlayer dielectric film 38, the emitter electrode 52, the current detection electrode 214, and the gate wiring 50.

Each of the current detection portion 26 and the transistor portion 70 has the trench portion 40 in the cross section. The gate conductive portion 44 of each trench portion 40 is connected to the gate wiring 50. Accordingly, a gate voltage is applied to each gate conductive portion 44.

An end portion of the trench portion 40 of the current detection portion 26 in the Y axis direction may be covered with the sense well region 28. In addition, an end portion of the trench portion 40 of the transistor portion 70 in the Y axis direction may be covered with an active well region 27. The active well region 27 is a P+ type region exposed on the upper surface 21 of the semiconductor substrate 10. The active well region 27 may be provided to a position deeper than that of the trench portion 40. The active well region 27 may be connected to the active well region 29 in FIG. 3. By covering the end portion of the trench portion 40 with the P+ type region, an electric field strength at the end portion of the trench portion 40 can be reduced.

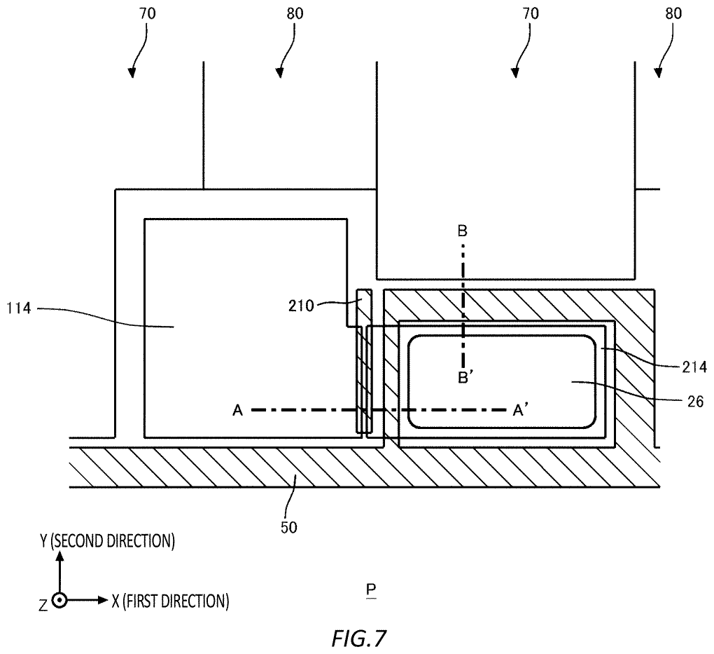

FIG. 7 is a view illustrating an example of a P region according to the first embodiment. The semiconductor device 100 of the present example further includes the built-in resistance portion 210 as compared with the reference example described with reference to FIGS. 4 to 6. The semiconductor device 100 of the present example may have a structure similar to that of the reference example described in FIGS. 4 to 6 except for a configuration to be particularly described.

The built-in resistance portion 210 and the gate wiring 50 are arranged side by side in the first direction (X axis direction) between the current detection portion 26 and the current detection pad 114. In the example of FIG. 7, the gate wiring 50 is arranged between the built-in resistance portion 210 and the current detection portion 26. However, the built-in resistance portion 210 is separated from the gate wiring 50.

A space between the current detection portion 26 and the current detection pad 114 refers to a space between at least a partial region of the current detection portion 26 and at least a partial region of the current detection pad 114. In the present example, at least a part of current detection portion 26 is arranged on a positive side in the X axis direction with respect to the built-in resistance portion 210 and gate wiring 50, and at least a part of current detection pad 114 is arranged on a negative side in the X axis direction. At least one of the built-in resistance portion 210 or the gate wiring 50 may overlap with the current detection pad 114.

Alignment of the built-in resistance portion 210 and the gate wiring 50 in the first direction (X axis direction) refers to a state where at least a partial region of built-in resistance portion 210 and the gate wiring 50 face each other in the first direction. 50% or more of the region of the built-in resistance portion 210 in the Y axis direction may face the gate wiring 50 in the first direction, and an entire region of the built-in resistance portion 210 in the Y axis direction may face the gate wiring 50 in the first direction. The built-in resistance portion 210 may have a region not facing the gate wiring 50 in the first direction. For example, the built-in resistance portion 210 may extend longer in the Y axis direction than the gate wiring 50 aligned with it in the first direction.

An end portion of the current detection portion 26 in the X axis direction is defined as the trench portion 40 provided at an outermost end in the X axis direction in the current detection portion 26. The built-in resistance portion 210 and the gate wiring 50 are arranged on the current detection pad 114 side with respect to the current detection portion 26.

The current detection electrode 214 of the present example is provided separately from the current detection pad 114. The current detection pad 114 of the present example is not in contact with the semiconductor substrate 10. That is, the metal forming the current detection pad 114 is not in contact with the semiconductor substrate 10. The current detection electrode 214 and the current detection pad 114 are connected to each other via the built-in resistance portion 210. Accordingly, the built-in resistance portion 210 connects the current detection portion 26 and the current detection pad 114.

With such a structure, the built-in resistance portion 210 can be provided between the current detection portion 26 and the current detection pad 114. The resistance value of the built-in resistance portion 210 may be adjusted by a shape such as a cross-sectional area and a width of the built-in resistance portion 210, may be adjusted by a material forming built-in resistance portion 210, or may be adjusted by a concentration of impurities added to the built-in resistance portion 210.

The built-in resistance portion 210 of the present example may be formed of polysilicon. Accordingly, the built-in resistance portion 210 can be easily provided above the semiconductor substrate 10.

Both the built-in resistance portion 210 and the gate wiring 50 may be formed of polysilicon. Accordingly, at least a part of a process of forming the built-in resistance portion 210 and the gate wiring 50 can be made common. Therefore, the built-in resistance portion 210 can be easily formed.

A thickness of the built-in resistance portion 210 in the Z axis direction and a thickness of the gate wiring 50 in the Z axis direction may be the same. Accordingly, the process of forming the built-in resistance portion 210 and the gate wiring 50 can be more easily made common. In another example, the thickness of the built-in resistance portion 210 in the Z axis direction may be smaller than the thickness of the gate wiring 50 in the Z axis direction. Accordingly, the resistance value of the built-in resistance portion 210 can be increased. The thickness of the built-in resistance portion 210 in the Z axis direction may be equal to or less than half of the thickness of the gate wiring 50 in the Z axis direction.

An impurity concentration (atoms/cm³) of the built-in resistance portion 210 and an impurity concentration of the gate wiring 50 may be the same. Accordingly, the process of forming the built-in resistance portion 210 and the gate wiring 50 can be more easily made common. In another example, the impurity concentration of the built-in resistance portion 210 may be lower than the impurity concentration of the gate wiring 50. Accordingly, the resistance value of the built-in resistance portion 210 can be increased. The impurity concentration of the built-in resistance portion 210 may be half or less of the impurity concentration of the gate wiring 50.

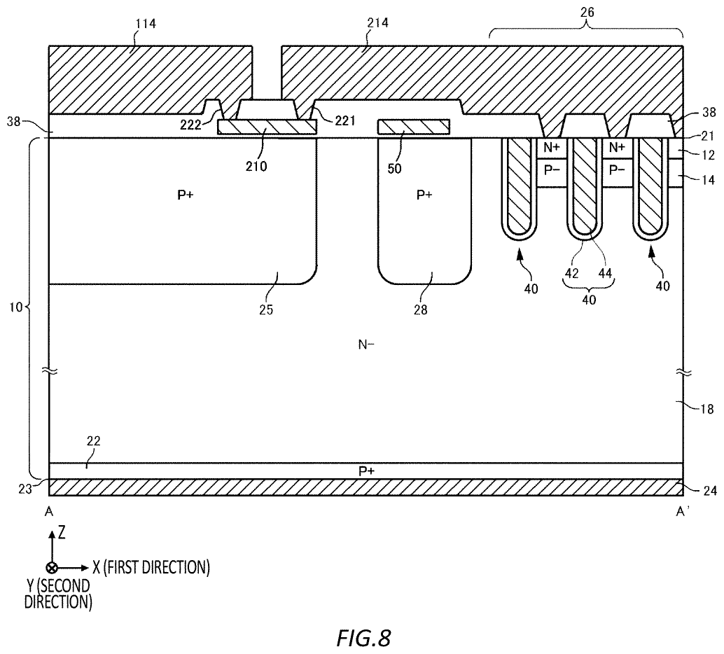

FIG. 8 is a view illustrating an example of a cross section A-A′ of FIG. 7. Similarly to the example of FIG. 5, the cross section A-A′ is an XZ plane passing through the current detection portion 26 and the current detection pad 114. As described with reference to FIG. 7, the semiconductor device 100 of the present example has the built-in resistance portion 210 in the cross section A-A′.

The built-in resistance portion 210 is arranged above the upper surface 21 of the semiconductor substrate 10. The built-in resistance portion 210 may be provided at a same height position as that of the gate wiring 50. The built-in resistance portion 210 of the present example overlaps with both the current detection electrode 214 and the current detection pad 114.

The built-in resistance portion 210 is electrically connected to the current detection electrode 214 and the current detection portion 26 by a first connection portion 221. The first connection portion 221 is provided to penetrate the interlayer dielectric film 38 from the current detection electrode 214 to the built-in resistance portion 210, and is in contact with a surface of the built-in resistance portion 210. The built-in resistance portion 210 is electrically connected to the current detection pad 114 by a second connection portion 222. The second connection portion 222 is provided to penetrate the interlayer dielectric film 38 from the current detection pad 114 to the built-in resistance portion 210, and is in contact with the surface of the built-in resistance portion 210.

The first connection portion 221 and the second connection portion 222 may be arranged side by side in the first direction (X axis direction). That is, the first connection portion 221 and the second connection portion 222 in the second direction (Y axis direction) may be the same in position. The first connection portion 221 may be elongated in the Y axis direction or elongated in the X axis direction. The second connection portion 222 may be elongated in the Y axis direction or elongated in the X axis direction. In the example of FIG. 8, one first connection portion 221 and one second connection portion 222 are provided. A plurality of the first connection portions 221 and a plurality of the second connection portions 222 may be provided side by side as described later.

At least a part of the gate wiring 50 may overlap with the sense well region 28. In the present example, a whole of the gate wiring 50 overlaps with the sense well region 28. At least a part of the built-in resistance portion 210 may overlap with the pad well region 25. In the present example, a whole of the built-in resistance portion 210 overlaps with the pad well region 25.

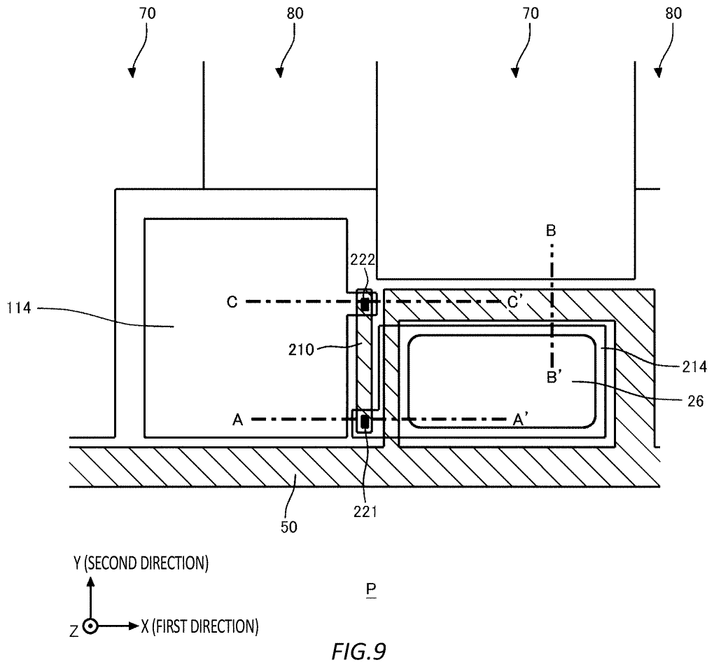

FIG. 9 is a view illustrating an example of a P region according to the second embodiment. The semiconductor device 100 of the present example is different from that of the first embodiment in the arrangement of the first connection portion 221 and the second connection portion 222. Other structures are similar to those of the first embodiment. The cross section B-B′ in each embodiment is similar to that in the example of FIG. 6, and thus description thereof is omitted.

The built-in resistance portion 210 is elongated in the second direction (Y axis direction). The first connection portion 221 and the second connection portion 222 of the present example are arranged at different positions in the Y axis direction. Accordingly, a distance from the first connection portion 221 to the second connection portion 222 can be increased, and a resistance value from the first connection portion 221 to the second connection portion 222 can be increased.

The current detection electrode 214 may have a first extending portion which extends to a position overlapping with the first connection portion 221. The current detection pad 114 may have a second extending portion which extends to a position overlapping with the second connection portion 222.

The gate wiring 50 arranged side by side with the built-in resistance portion 210 in the X axis direction may also be elongated in the Y axis direction. A length of the built-in resistance portion 210 in the Y axis direction may be longer or shorter than that of the gate wiring 50 arranged side by side with it.

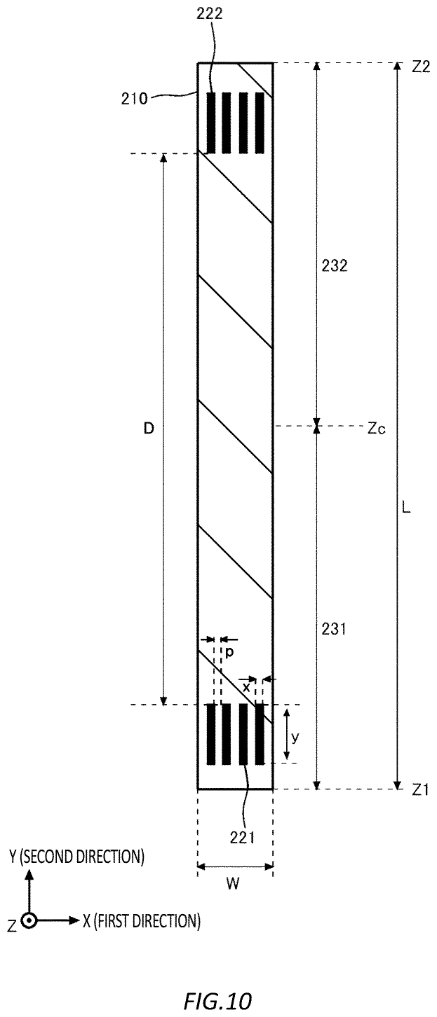

FIG. 10 is an enlarged view of the built-in resistance portion 210. A center position of the built-in resistance portion 210 in the Y axis direction is defined as Zc, and both end positions of the built-in resistance portion 210 are defined as Z1 and Z2. In addition, a region obtained by equally dividing the built-in resistance portion 210 in the Y axis direction is defined as a first region 231 and a second region 232. In the present example, the first region 231 is a region from the position Zc to the position Z1, and the second region 232 is a region from the position Zc to the position Z2.

The first connection portion 221 may be arranged in the first region 231, and the second connection portion 222 may be arranged in the second region 232. Accordingly, the distance between the first connection portion 221 and the second connection portion 222 can be increased, and the resistance value between the first connection portion 221 and the second connection portion 222 can be increased. A distance D between the first connection portion 221 and the second connection portion 222 in the Y axis direction may be equal to or greater than a half of a length L of the built-in resistance portion 210 in the Y axis direction, or may be equal to or greater than ¾.

A width W of the built-in resistance portion 210 in the X axis direction may be the same as or different from a width of the gate wiring 50, which is arranged side by side with it, in the X axis direction. The width W of the built-in resistance portion 210 in the X axis direction may be less than 100%, equal to or less than 50%, or equal to or less than 25% of the width of the gate wiring 50, which is arranged side by side with it, in the X axis direction. By reducing the width W of the built-in resistance portion 210, the resistance value between the first connection portion 221 and the second connection portion 222 can be increased.

A plurality of the first connection portions 221 may be provided side by side. In the example of FIG. 10, the plurality of first connection portions 221 are arranged side by side in the X axis direction. A width of each of the first connection portions 221 in the X axis direction is defined as x, its length in the Y axis direction is defined as y, and an interval between the first connection portions 221 in the X axis direction is defined as p. The width x may be 0.4 μm or more and 0.5 μm or less. The length y may be 4 μm or more and 8 μm or less. The interval p may be 1 μm or more and 2 μm or less. A number of the first connection portions 221 may be two or more and six or less. A plurality of second connection portions 222 may also be provided side by side. Arrangement, a number, a width, a length, and an interval of the second connection portion 222 in the X axis direction may be similar to those of the first connection portion 221.

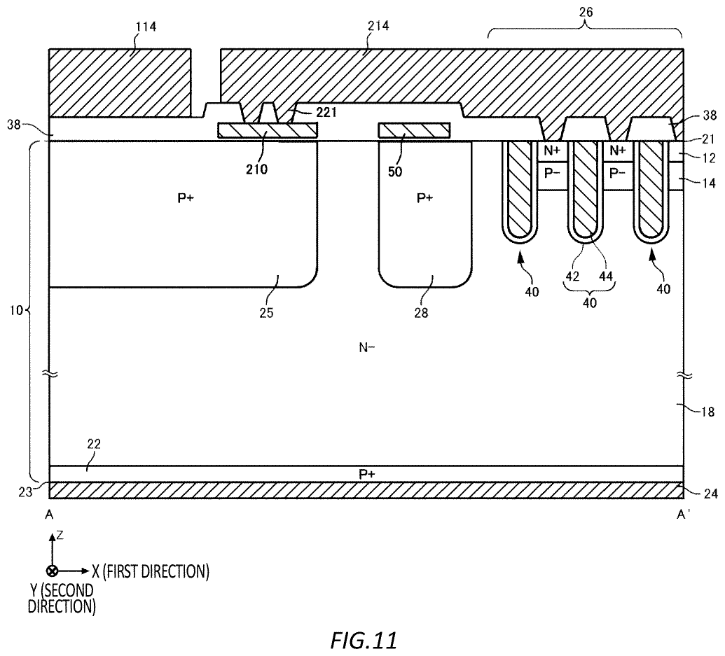

FIG. 11 is a view illustrating an example of a cross section A-A′ of FIG. 9. The cross section A-A′ is an XZ plane passing through the first connection portion 221. In the cross section, the built-in resistance portion 210 and the current detection electrode 214 are connected by the first connection portion 221.

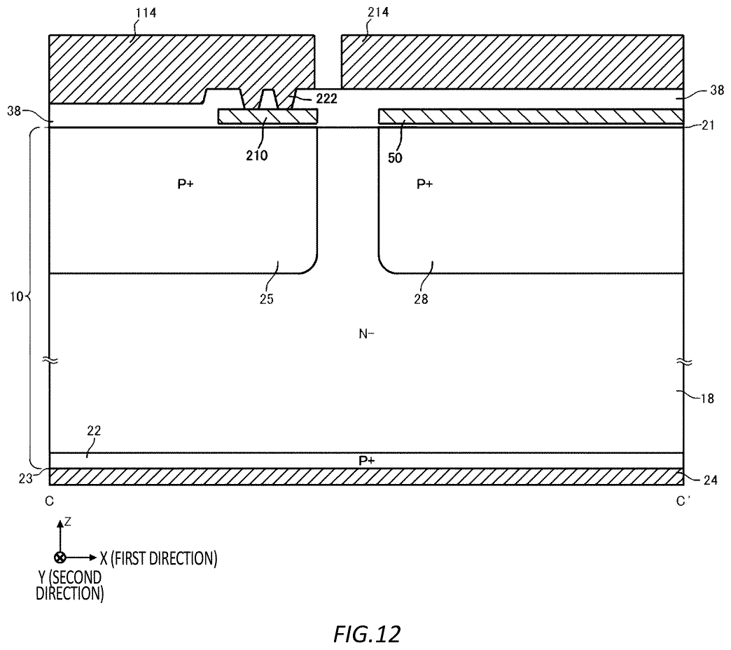

FIG. 12 is a view illustrating an example of a cross section C-C′ of FIG. 9. The cross section C-C′ is an XZ plane passing through the second connection portion 222. In the cross section, the built-in resistance portion 210 and the current detection pad 114 are connected by the second connection portion 222.

The second connection portion 222 may be arranged facing the current detection portion 26 in the X axis direction, or may not be arranged facing the current detection portion 26. The second connection portion 222 of the present example is arranged facing the gate wiring 50 arranged between the current detection portion 26 and the transistor portion 70 in the X axis direction. Accordingly, the second connection portion 222 can be arranged away from the first connection portion 221.

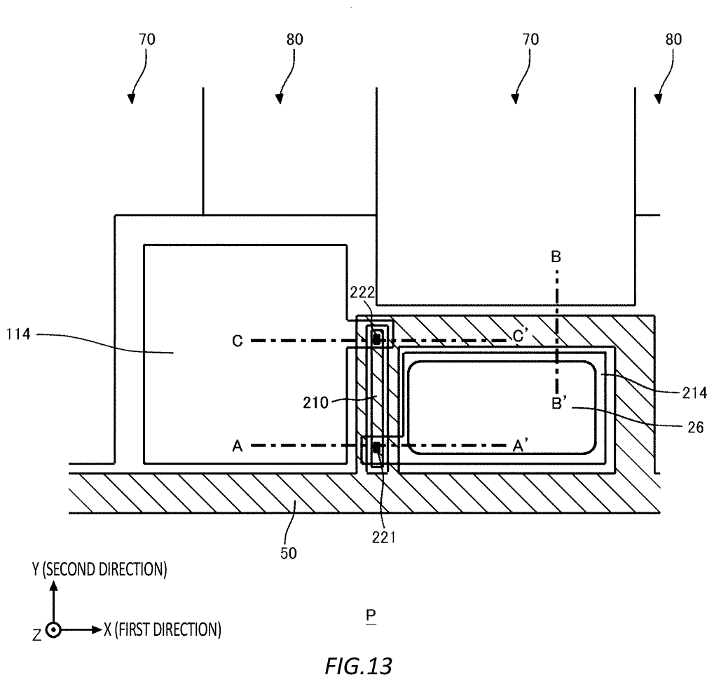

FIG. 13 is a view illustrating an example of a P region according to a third embodiment. The present example is different from the first and second embodiments in the arrangement of the gate wiring 50 and the built-in resistance portion 210. Other structures are similar to any of the first and second embodiments. In the example of FIG. 13, the first connection portion 221 and the second connection portion 222 are arranged similarly to the second embodiment, but the first connection portion 221 and the second connection portion 222 may be arranged similarly to the first embodiment.

A plurality of gate wirings 50 of the present example are provided side by side in the X axis direction between the current detection portion 26 and the current detection pad 114. The gate wirings 50 are connected to each other at their end portions in the Y axis direction.

Between the current detection portion 26 and the current detection pad 114, the built-in resistance portion 210 of the present example is sandwiched between two gate wirings 50 in the X axis direction. The built-in resistance portion 210 may also be sandwiched between the gate wirings 50 in the Y axis direction. The built-in resistance portion 210 of the present example is arranged so as to be surrounded by the gate wiring 50.

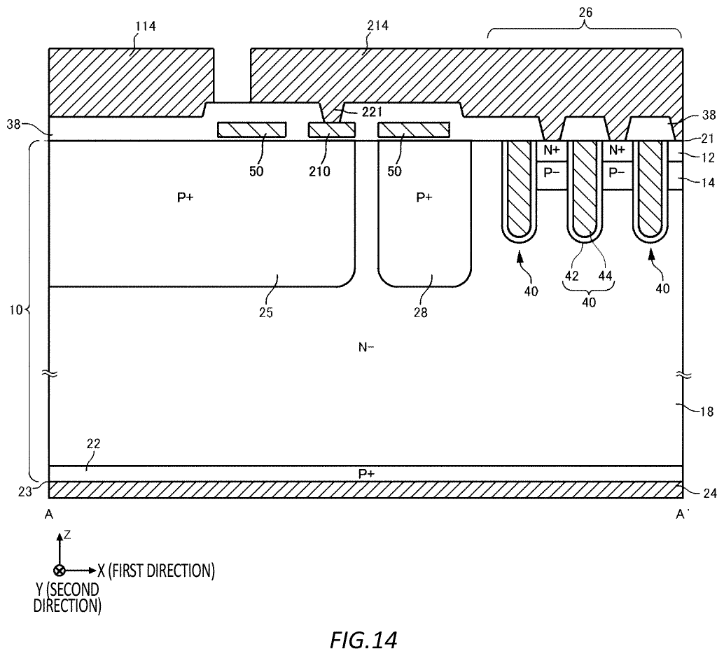

FIG. 14 is a view illustrating an example of a cross section A-A′ of FIG. 13. The cross section A-A′ is an XZ plane passing through the first connection portion 221. As described with reference to FIG. 13, the built-in resistance portion 210 is arranged to be sandwiched between two gate wirings 50. In the cross section, the built-in resistance portion 210 and the current detection electrode 214 are connected by the first connection portion 221.

At least a part of the gate wiring 50 between the built-in resistance portion 210 and the current detection portion 26 may overlap with the sense well region 28. In the present example, the whole of the gate wiring 50 overlaps with the sense well region 28. At least a part of the built-in resistance portion 210 may overlap with the pad well region 25. In the present example, the whole of the built-in resistance portion 210 overlaps with the pad well region 25. At least a part of the gate wiring 50 between the built-in resistance portion 210 and the current detection pad 114 may overlap with the pad well region 25. In the present example, the whole of the gate wiring 50 overlaps with the pad well region 25.

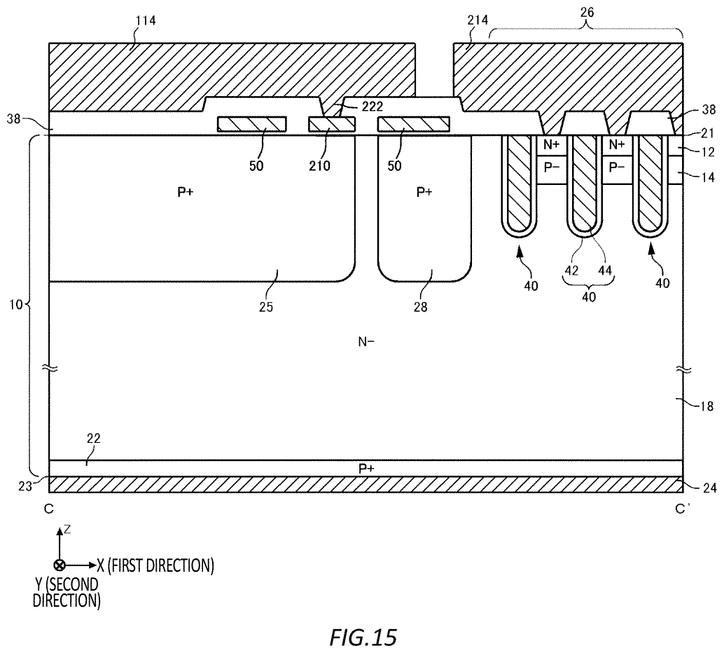

FIG. 15 is a view illustrating an example of a cross section C-C′ of FIG. 13. The cross section C-C′ is an XZ plane passing through the second connection portion 222. As described with reference to FIG. 13, the built-in resistance portion 210 is arranged to be sandwiched between two gate wirings 50. In the cross section, the built-in resistance portion 210 and the current detection pad 114 are connected by the second connection portion 222.

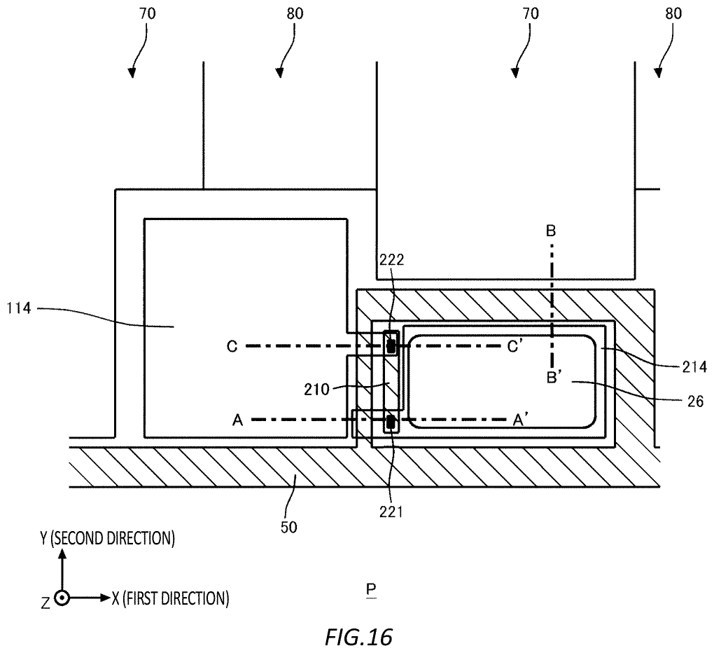

FIG. 16 is a view illustrating an example of a P region according to a fourth embodiment. The present example is different from the first and second embodiments in the arrangement of the gate wiring 50 and the built-in resistance portion 210. Other structures are similar to any of the first and second embodiments. In the example of FIG. 16, the first connection portion 221 and the second connection portion 222 are arranged similarly to the second embodiment, but the first connection portion 221 and the second connection portion 222 may be arranged similarly to the first embodiment.

The gate wiring 50 of the present example is arranged between the built-in resistance portion 210 and the current detection pad 114. At least a part of the gate wiring 50 may overlap with the current detection pad 114. The built-in resistance portion 210 of the present example is sandwiched between the gate wirings 50 in the Y axis direction.

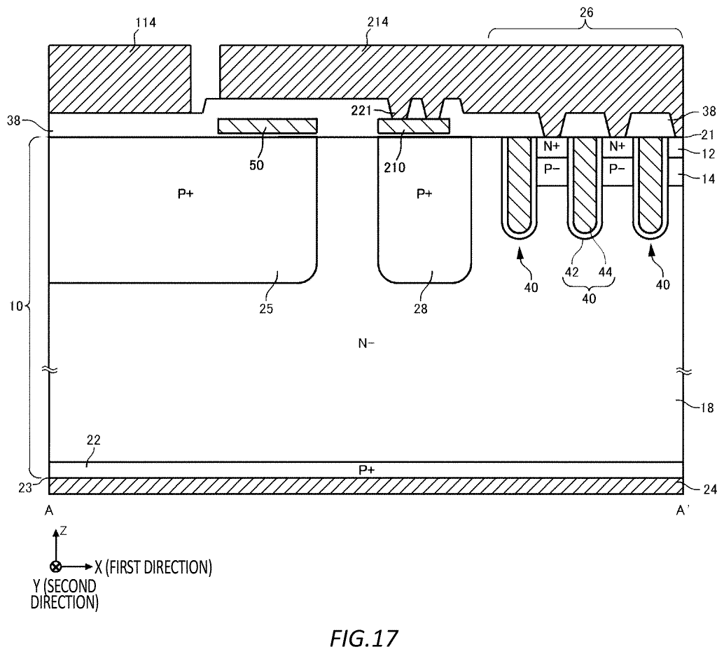

FIG. 17 is a view illustrating an example of a cross section A-A′ of FIG. 16. The cross section A-A′ is an XZ plane passing through the first connection portion 221. As described with reference to FIG. 16, the built-in resistance portion 210 is arranged to be sandwiched between the gate wiring 50 and the current detection electrode 214. In the cross section, the built-in resistance portion 210 and the current detection electrode 214 are connected by the first connection portion 221.

At least a part of the gate wiring 50 may overlap with the pad well region 25. In the present example, the whole of the gate wiring 50 overlaps with the pad well region 25. At least a part of the built-in resistance portion 210 may overlap with the sense well region 28. In the present example, the whole of the built-in resistance portion 210 overlaps with the sense well region 28.

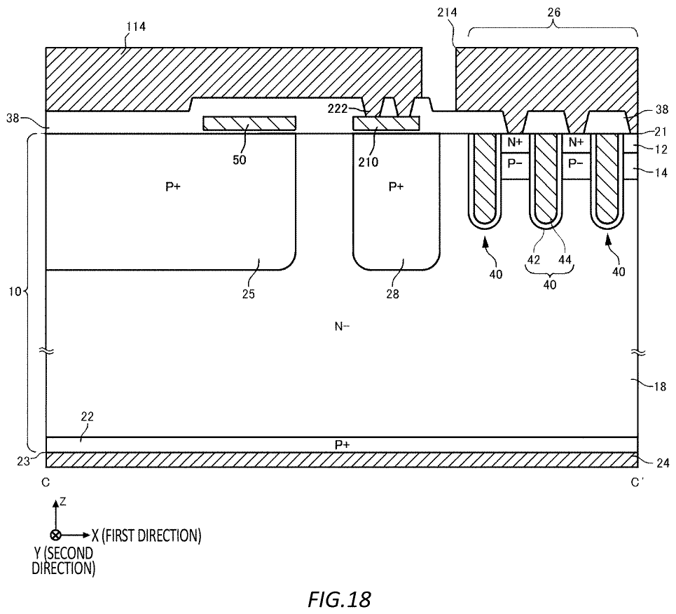

FIG. 18 is a view illustrating an example of a cross section C-C′ of FIG. 16. The cross section C-C′ is an XZ plane passing through the second connection portion 222. In the cross section, the built-in resistance portion 210 and the current detection pad 114 are connected by the second connection portion 222.

The built-in resistance portion 210 described with reference to FIGS. 7 to 18 has a linear shape extending in the Y axis direction. The built-in resistance portion 210 of another example may have a portion extending in the Y axis direction and a portion extending in another direction different from the Y axis direction. That is, the built-in resistance portion 210 may have a bent shape in top view.

For example, as illustrated in FIG. 13, in a configuration in which the built-in resistance portion 210 is surrounded by the gate wiring 50, the built-in resistance portion 210 may have a portion extending in the X axis direction between the current detection portion 26 and the transistor portion 70. In this case, one of the first connection portion 221 or the second connection portion 222 may be arranged between the current detection portion 26 and the transistor portion 70, and another connection portion may be arranged between the current detection portion 26 and the current detection pad 114. Accordingly, the length of the built-in resistance portion 210 between the first connection portion 221 and the second connection portion 222 can be further increased, and the resistance value can be increased.

The built-in resistance portion 210 extending in the X axis direction may be sandwiched between two gate wirings 50 in the Y axis direction. The gate wiring 50 between the built-in resistance portion 210 and the transistor portion 70 may be connected to the gate conductive portion 44 of the transistor portion 70. The gate wiring 50 between the built-in resistance portion 210 and the current detection portion 26 may be connected to the gate conductive portion 44 of the current detection portion 26.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such changes or improvements are made may be included in the technical scope of the present invention.

The present specification and the drawings also disclose inventions according to the following items.

### (Supplementary Note 1)

A semiconductor device including a semiconductor substrate, including:
a transistor portion which is provided inside the semiconductor substrate and includes a gate conductive portion;
a current detection portion which is provided inside the semiconductor substrate and through which a detection current corresponding to a main current of the transistor portion flows;
a current detection pad which is arranged above the semiconductor substrate and arranged side by side with the current detection portion in a first direction;
a built-in resistance portion which is provided above the semiconductor substrate and connects the current detection portion and the current detection pad; and
a gate wiring which is arranged above the semiconductor substrate and is connected to the gate conductive portion, in which
the built-in resistance portion and the gate wiring are arranged side by side in the first direction between the current detection portion and the current detection pad.

### (Supplementary Note 2)

The semiconductor device according to supplementary note 1, in which
the built-in resistance portion and the gate wiring are formed of polysilicon.

### (Supplementary Note 3)

The semiconductor device according to supplementary note 2, in which
the built-in resistance portion and the gate wiring have a same thickness.

### (Supplementary Note 4)

The semiconductor device according to any one of supplementary notes 1 to 3, in which
the built-in resistance portion is elongated in a second direction different from the first direction in top view.

### (Supplementary Note 5)

The semiconductor device according to supplementary note 4, further including:
a first connection portion which is in contact with the built-in resistance portion and electrically connects the built-in resistance portion and the current detection portion; and
a second connection portion which is in contact with the built-in resistance portion and electrically connects the built-in resistance portion and the current detection pad, in which
the first connection portion and the second connection portion are arranged at different positions in the second direction.

### (Supplementary Note 6)

The semiconductor device according to supplementary note 5, in which
the first connection portion is arranged in a first region of the first region and a second region obtained by equally dividing the built-in resistance portion in the second direction, and
the second connection portion is arranged in the second region.

### (Supplementary Note 7)

The semiconductor device according to supplementary note 4, in which
the gate wiring is elongated in the second direction.

### (Supplementary Note 8)

The semiconductor device according to supplementary note 7, in which
the gate wiring is arranged between the built-in resistance portion and the current detection portion.

### (Supplementary Note 9)

The semiconductor device according to supplementary note 7, in which
the gate wiring is arranged between the built-in resistance portion and the current detection pad.

### (Supplementary Note 10)

The semiconductor device according to supplementary note 7, in which
a plurality of gate wirings including the gate wiring are provided side by side in the first direction between the current detection portion and the current detection pad, and
between the current detection portion and the current detection pad, the built-in resistance portion is sandwiched between two gate wirings including the gate wiring.

### (Supplementary Note 11)

The semiconductor device according to any one of supplementary notes 1 to 3, in which
the current detection pad is not in contact with the semiconductor substrate.

### (Supplementary Note 12)

The semiconductor device according to any one of supplementary notes 1 to 3, in which
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further includes a pad well region of the second conductivity type which is provided inside the semiconductor substrate and provided from an upper surface of the semiconductor substrate to a position deeper than that of the base region, and
the pad well region overlaps with at least a part of the current detection pad in top view.

### (Supplementary Note 13)

The semiconductor device according to supplementary note 12, in which
the pad well region overlaps with a whole of the current detection pad in top view.

### (Supplementary Note 14)

The semiconductor device according to any one of supplementary notes 1 to 3, in which
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further includes a well region of the second conductivity type which is provided inside the semiconductor substrate and provided from an upper surface of the semiconductor substrate to a position deeper than that of the base region, and
the well region overlaps with at least a part of the built-in resistance portion in top view.

### (Supplementary Note 15)

The semiconductor device according to supplementary note 14, in which
the well region overlaps with a whole of the built-in resistance portion in top view.

### (Supplementary Note 16)

The semiconductor device according to any one of supplementary notes 1 to 3, in which
a resistance value of the built-in resistance portion is larger than a resistance value of an external resistance portion connected in series with the built-in resistance portion and the current detection pad.

### (Supplementary Note 17)

The semiconductor device according to any one of supplementary notes 1 to 3, in which
the current detection pad is arranged from a position overlapping with the built-in resistance portion in top view to a position farther from the current detection portion than the built-in resistance portion in the first direction.

### (Supplementary Note 18)

The semiconductor device according to any one of supplementary notes 1 to 3, in which
a length of the current detection pad is longer than a length of the current detection portion in a second direction perpendicular to the first direction in top view.

### (Supplementary Note 19)

The semiconductor device according to any one of supplementary notes 1 to 3, in which
the gate wiring surrounds the current detection portion in top view.

### (Supplementary Note 20)

The semiconductor device according to any one of supplementary notes 1 to 3, in which
the current detection portion is arranged side by side with the transistor portion in a second direction perpendicular to the first direction in top view.

### (Supplementary Note 21)

The semiconductor device according to any one of supplementary notes 1 to 3, in which
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further includes a well region of the second conductivity type which is provided inside the semiconductor substrate and provided from an upper surface of the semiconductor substrate to a position deeper than that of the base region, and
the well region overlaps with at least a part of the gate wiring in top view.

### (Supplementary Note 22)

A semiconductor module including: a semiconductor device including a semiconductor substrate; and an external resistance portion connected to the semiconductor device, in which
the semiconductor device includes
a transistor portion which is provided inside the semiconductor substrate and includes a gate conductive portion,
a current detection portion which is provided inside the semiconductor substrate and through which a detection current corresponding to a main current of the transistor portion flows,
a current detection pad which is arranged above the semiconductor substrate, and
a built-in resistance portion which is provided above the semiconductor substrate and connects the current detection portion and the current detection pad, and
the external resistance portion is connected in series with the built-in resistance portion and the current detection pad.

### (Supplementary Note 23)

The semiconductor module according to supplementary note 22, in which
a resistance value of the built-in resistance portion is larger than a resistance value of the external resistance portion.

### (Supplementary Note 24)

The semiconductor module according to supplementary note 23, in which
the resistance value of the built-in resistance portion is three times or more and ten times or less the resistance value of the external resistance portion.

### (Supplementary Note 25)

The semiconductor module according to supplementary note 23 or 24, in which
the resistance value of the built-in resistance portion is 6Ω or more.

### (Supplementary Note 26)

The semiconductor module according to supplementary note 25, in which
the resistance value of the built-in resistance portion is 20Ω or less.

### (Supplementary Note 27)

The semiconductor module according to supplementary note 23 or 24, in which
when a rated current of the semiconductor device is Ir (A), the resistance value (Ω) of the built-in resistance portion is Ir/50 or more.

### (Supplementary Note 28)

The semiconductor module according to supplementary note 27, in which
the resistance value of the built-in resistance portion is Ir/15 or less.

What is claimed is:

1. A semiconductor device including a semiconductor substrate, comprising:
a transistor portion which is provided inside the semiconductor substrate and includes a gate conductive portion;
a current detection portion which is provided inside the semiconductor substrate and through which a detection current corresponding to a main current of the transistor portion flows;
a current detection pad which is arranged above the semiconductor substrate and arranged side by side with the current detection portion in a first direction;
a built-in resistance portion which is provided above the semiconductor substrate and connects the current detection portion and the current detection pad; and
a gate wiring which is arranged above the semiconductor substrate and is connected to the gate conductive portion, wherein
the built-in resistance portion and the gate wiring are arranged side by side in the first direction between the current detection portion and the current detection pad.

2. The semiconductor device according to claim 1, wherein
the built-in resistance portion is elongated in a second direction different from the first direction in top view,
the semiconductor device further comprises: a first connection portion which is in contact with the built-in resistance portion and electrically connects the built-in resistance portion and the current detection portion; and
a second connection portion which is in contact with the built-in resistance portion and electrically connects the built-in resistance portion and the current detection pad, and
the first connection portion and the second connection portion are arranged at different positions in the second direction.

3. The semiconductor device according to claim 2, wherein
the first connection portion is arranged in a first region of the first region and a second region obtained by equally dividing the built-in resistance portion in the second direction, and
the second connection portion is arranged in the second region.

4. The semiconductor device according to claim 1, wherein
the built-in resistance portion is elongated in a second direction different from the first direction in top view, and
a gate wiring is elongated in the second direction and is arranged between the built-in resistance portion and the current detection pad.

5. The semiconductor device according to claim 1, wherein
the built-in resistance portion is elongated in a second direction different from the first direction in top view,
the gate wiring is elongated in the second direction, and a plurality of gate wirings including the gate wiring are provided side by side in the first direction between the current detection portion and the current detection pad, and
between the current detection portion and the current detection pad, the built-in resistance portion is sandwiched between two gate wirings including the gate wiring.

6. The semiconductor device according to claim 1, wherein
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further comprises a pad well region of the second conductivity type which is provided inside the semiconductor substrate and provided from an upper surface of the semiconductor substrate to a position deeper than that of the base region, and
the pad well region overlaps with at least a part of the current detection pad in top view.

7. The semiconductor device according to claim 6, wherein
the pad well region overlaps with a whole of the current detection pad in top view.

8. The semiconductor device according to claim 1, wherein
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further comprises a well region of the second conductivity type which is provided inside the semiconductor substrate and provided from an upper surface of the semiconductor substrate to a position deeper than that of the base region, and
the well region overlaps with at least a part of the built-in resistance portion in top view.

9. The semiconductor device according to claim 8, wherein
the well region overlaps with a whole of the built-in resistance portion in top view.

10. The semiconductor device according to claim 1, wherein
a resistance value of the built-in resistance portion is larger than a resistance value of an external resistance portion connected in series with the built-in resistance portion and the current detection pad.

11. The semiconductor device according to claim 1, wherein
the current detection pad is arranged from a position overlapping with the built-in resistance portion in top view to a position farther from the current detection portion than the built-in resistance portion in the first direction.

12. The semiconductor device according to claim 1, wherein
a length of the current detection pad is longer than a length of the current detection portion in a second direction perpendicular to the first direction in top view.

13. The semiconductor device according to claim 1, wherein
the gate wiring surrounds the current detection portion in top view.

14. The semiconductor device according to claim 1, wherein
the current detection portion is arranged side by side with the transistor portion in a second direction perpendicular to the first direction in top view.

15. The semiconductor device according to claim 1, wherein
the transistor portion includes
a drift region of a first conductivity type which is provided inside the semiconductor substrate,
an emitter region of the first conductivity type which is arranged above the drift region inside the semiconductor substrate and has a concentration higher than that of the drift region, and
a base region of a second conductivity type which is arranged between the drift region and the emitter region inside the semiconductor substrate,
the semiconductor device further comprises a well region of the second conductivity type which is provided inside the semiconductor substrate and provided from an upper surface of the semiconductor substrate to a position deeper than that of the base region, and
the well region overlaps with at least a part of the gate wiring in top view.

16. A semiconductor module comprising: a semiconductor device including a semiconductor substrate; and an external resistance portion connected to the semiconductor device, wherein
the semiconductor device includes
a transistor portion which is provided inside the semiconductor substrate and includes a gate conductive portion,
a current detection portion which is provided inside the semiconductor substrate and through which a detection current corresponding to a main current of the transistor portion flows,
a current detection pad which is arranged above the semiconductor substrate, and
a built-in resistance portion which is provided above the semiconductor substrate and connects the current detection portion and the current detection pad, and
the external resistance portion is connected in series with the built-in resistance portion and the current detection pad.

17. The semiconductor module according to claim 16, wherein
a resistance value of the built-in resistance portion is larger than a resistance value of the external resistance portion.

18. The semiconductor module according to claim 17, wherein
the resistance value of the built-in resistance portion is three times or more and ten times or less the resistance value of the external resistance portion.

19. The semiconductor module according to claim 17, wherein
the resistance value of the built-in resistance portion is 6Ω or more and 20Ω or less.

20. The semiconductor module according to claim 17, wherein
when a rated current of the semiconductor device is Ir (A), the resistance value (Ω) of the built-in resistance portion is Ir/50 or more and Ir/15 or less.
